(19) United States
(12) Patent Application Publication
(10) Pub. No.: US 2025/0366344 A1
(43) Pub. Date: Nov. 27, 2025

(54) DISPLAY DEVICE AND METHOD OF EVALUATING THE SAME

(71) Applicant: Samsung Display Co., LTD., Yongin-si (KR)

(72) Inventor: Seung Cheol KO, Yongin-si (KR)

(73) Assignee: Samsung Display Co., LTD., Yongin-si (KR)

(21) Appl. No.: 19/009,109

(22) Filed: Jan. 3, 2025

(30) Foreign Application Priority Data
May 22, 2024 (KR) 10-2024-0066600

(51) Int. Cl. H10K 59/80; H10K 59/122; H10K 71/70

(52) U.S. Cl. CPC H10K 59/80515; H10K 59/122; H10K 71/70

(57) ABSTRACT

A display device includes a substrate, a pixel circuit layer on the substrate, anodes spaced apart from each other on the pixel circuit layer, a pixel defining layer on portions of the anodes and the pixel circuit layer, and patterns on the pixel defining layer. An edge portion of each of the patterns may be tapered.

### CROSS-REFERENCE TO RELATED APPLICATION(S)

This application claims priority to and benefits of Korean Patent Application No. 10-2024-0066600 under 35 U.S.C. § 119, filed on May 22, 2024, in the Korean Intellectual Property Office, the entire contents of which are incorporated herein by reference.

### BACKGROUND

### 1. Technical Field

Embodiments relate to a display device and a method of evaluating the display device.

### 2. Description of the Related Art

As information technology develops, the importance of a display device, which is a connection medium between a user and information, has been highlighted. Thus, the use of a display device such as a liquid crystal display device and an organic light emitting display device is increasing.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a display device capable of measuring misalignment of emission layers and a method of evaluating the display device.

However, embodiments are not limited to those set forth herein. The above and other embodiments will become more apparent to one of ordinary skill in the art to which the disclosure pertains by referencing the detailed description of the disclosure given below.

According to an embodiment, a display device may include a substrate, a pixel circuit layer disposed on the substrate, anodes spaced apart from each other and disposed on the pixel circuit layer, a pixel defining layer disposed on portions of the anodes and the pixel circuit layer, and patterns formed on the pixel defining layer, wherein an edge portion of each of the patterns may be tapered.

In an embodiment, the patterns may be disposed between the anodes and may not overlap the anodes.

In an embodiment, the patterns may be formed to be adjacent to corner portions of each of the anodes.

In an embodiment, each of the patterns may have a cross shape in plan view, and the patterns may be spaced apart from each other.

In an embodiment, a width of each of the patterns may decrease as being closer to the substrate.

In an embodiment, a maximum value of the width of each of the patterns may be about 0.5 μm or less.

In an embodiment, a depth of each of the patterns may be in a range of about 3,000 angstrom to about 5,000 angstrom.

In an embodiment, a taper angle of the edge portion may be about 75° or more and less than about 90°.

In an embodiment, each of the patterns may have a matrix shape in plan view, and the patterns may be spaced apart from each other.

According to an embodiment, a display device may include a substrate, a pixel circuit layer disposed on the substrate, anodes spaced apart from each other and disposed on the pixel circuit layer, a pixel defining layer disposed on portions of the anodes and the pixel circuit layer, and a pattern formed on the pixel defining layer and having a matrix shape, wherein an edge portion of the pattern may be tapered.

According to an embodiment, a method of evaluating a display device including a pattern disposed on a pixel defining layer and having a tapered edge portion may include detecting a reference boundary line of a first emission layer, detecting boundary lines of a second emission layer, obtaining a degree of alignment of the first emission layer and the second emission layer based on the reference boundary line and the boundary lines, and determining whether the display device is defective, based on the degree of alignment.

In an embodiment, the reference boundary line may be a boundary line between an area of the first emission layer that overlaps the tapered edge portion of the pattern and an area of the first emission layer that overlaps a lower surface of the pattern.

In an embodiment, the boundary lines of the second emission layer may include a first boundary line between an area of the second emission layer that overlaps the first emission layer and an area of the first emission layer that overlaps the lower surface of the pattern, and a second boundary line between an area of the second emission layer that overlaps the first emission layer and an area of the second emission layer that overlaps the lower surface of the pattern.

In an embodiment, the obtaining of the degree of alignment of the first emission layer and the second emission layer may include obtaining a first gap between the reference boundary line and the first boundary line, obtaining a second gap between the reference boundary line and the second boundary line, and obtaining a width of a color mix area where the first emission layer overlaps the second emission layer, based on the first gap and the second gap.

In an embodiment, the determining of whether the display device is defective may include checking whether the width of the color mix area corresponds to a reference value.

According to an embodiment, a method of evaluating a display device including a pattern formed on a pixel defining layer and having a tapered edge portion may include detecting boundary lines of a first emission layer, detecting a boundary line of a second emission layer, obtaining a degree of alignment of the first emission layer and the second emission layer, based on the boundary lines of the first emission layer and the boundary line of the second emission layer, and determining whether the display device is defective, based on the degree of alignment.

In an embodiment, the boundary lines of the first emission layer may include a reference boundary line between an area of the first emission layer that overlaps the tapered edge portion of the pattern and an area of the first emission layer that overlaps a lower surface of the pattern, and a boundary line between the area of the first emission layer that overlaps the lower surface of the pattern and an area of the pattern.

In an embodiment, the boundary line of the second emission layer may be a boundary line between an area of the second emission layer that overlaps the lower surface of the pattern and the area of the pattern.

In an embodiment, the obtaining of the degree of alignment of the first emission layer and the second emission layer may include obtaining a first gap between the reference boundary line and the boundary line of the first emission layer, obtaining a second gap between the reference boundary line and the boundary line of the second emission layer, and obtaining a width of a color loss area where the first emission layer does not overlap the second emission layer, based on the first gap and the second gap.

In an embodiment, the determining of whether the display device is defective may include checking whether the width of the color loss area corresponds to a preset value.

### BRIEF DESCRIPTION OF THE DRAWINGS

The above and other features of the disclosure will become more apparent by describing in further detail embodiments thereof with reference to the accompanying drawings, in which:

FIG. 1 is a schematic block diagram illustrating a display device in accordance with an embodiment.

FIG. 2 is a schematic block diagram illustrating a sub-pixel in accordance with an embodiment.

FIG. 3 is a schematic diagram of an equivalent circuit of a sub-pixel in accordance with an embodiment.

FIG. 4 is a schematic plan view illustrating a display panel in accordance with an embodiment.

FIG. 5 is a schematic plan view illustrating a pixel in accordance with an embodiment.

FIG. 6 is a schematic cross-sectional view taken along line I-I′ of FIG. 5 in accordance with an embodiment.

FIG. 7 is a schematic diagram illustrating a deposition process in accordance with an embodiment.

FIG. 8 is a schematic plan view illustrating the arrangement of patterns in accordance with an embodiment.

FIG. 9 is a schematic cross-sectional view taken along line II-II′ of FIG. 8 in accordance with an embodiment.

FIGS. 10 to 13 are schematic diagrams describing a method for evaluating a display device in accordance with an embodiment.

FIGS. 14 and 15 are schematic diagrams describing a method for evaluating a display device in accordance with an embodiment.

FIG. 16 is a schematic plan view illustrating the arrangement of patterns in accordance with an embodiment.

FIG. 17 is a schematic plan view illustrating the arrangement of patterns in accordance with an embodiment.

FIG. 18 is a schematic block diagram illustrating a display system in accordance with an embodiment.

FIG. 19 is a schematic perspective view illustrating an application example of the display system of FIG. 18.

FIG. 20 is a schematic diagram illustrating a head mounted display (HMD) of FIG. 19 that is worn by a user.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Embodiments of the present disclosure will be described in detail with reference to the accompanying drawings.

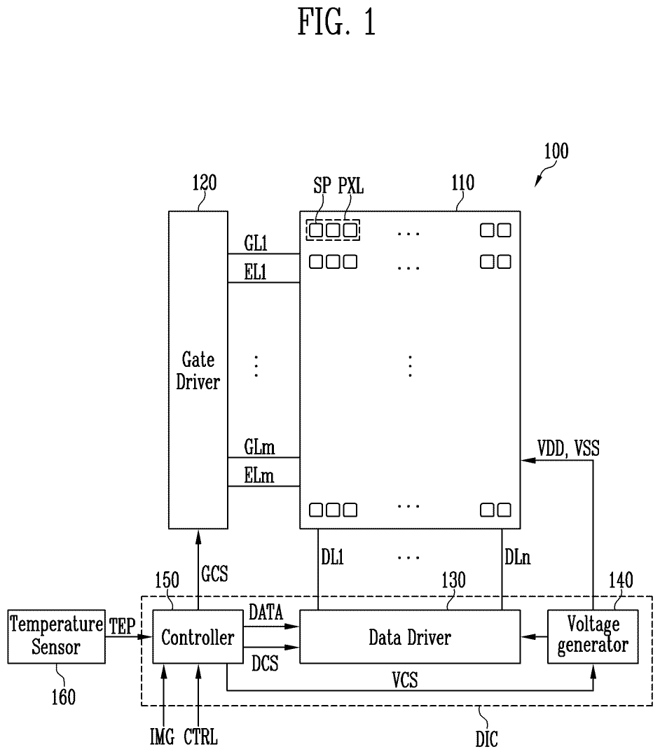

FIG. 1 is a schematic block diagram illustrating a display device in accordance with an embodiment.

Referring to FIG. 1, a display device 100 may include a display panel 110, a gate driver 120, a data driver 130, a voltage generator 140, and a controller 150.

The display panel 110 may include sub-pixels SP. The sub-pixels SP may be connected (e.g., electrically connected) to the gate driver 120 through first to m-th gate lines GL1 to GLm. The sub-pixels SP may be connected (e.g., electrically connected) to the data driver 130 through first to n-th data lines DL1 to DLn.

The sub-pixels SP may each include at least one light emitting element that generates light. Accordingly, the sub-pixels SP may each generate light of a specific color, such as red, green, blue, cyan, magenta, yellow, etc. Two or more sub-pixels among the sub-pixels SP may constitute (or form) a pixel (e.g., single pixel) PXL. For example, as illustrated in FIG. 1, three sub-pixels may constitute (or form) a pixel e.g., single pixel) PXL.

The gate driver 120 may be connected (e.g., electrically connected) to the sub-pixels SP arranged in the row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating the start of each frame, a horizontal synchronization signal for outputting the gate signals in synchronization with a timing at which data signals are applied, etc.

In embodiments, first to m-th emission control lines EL1 to ELm connected (e.g., electrically connected) to the sub-pixels SP arranged in the row direction may be further provided. For example, the gate driver 120 may include an emission control driver that controls the first to m-th emission control lines EL1 to ELm, and the emission control driver may operate under the control of the controller 150.

The gate driver 120 may be disposed on a side of the display panel 110. However, embodiments are not limited thereto. For example, the gate driver 120 may be divided into two or more physically and/or logically separated drivers. Such drivers may be disposed on a side of the display panel 110 and another side of the display panel 110 opposite to the side. For example, the gate driver 120 may be arranged around the display panel 110 in various shapes in accordance with embodiments.

The data driver 130 may be connected (e.g., electrically connected) to the sub-pixels SP arranged in the column direction through the first to n-th data lines DL1 to DLn. The data driver 130 may receive image data DATA and a data control signal DCS from the controller 150. The data driver 130 may operate in response to the data control signal DCS. In embodiments, the data control signal DCS may include a source start pulse, a source shift clock, a source output enable signal, etc.

The data driver 130 may apply, to the first to n-th data lines DL1 to DLn, data signals having gray scale voltages corresponding to the image data DATA by using the voltages from the voltage generator 140. In case that the gate signal is applied to each of the first to m-th gate lines GL1 to GLm, the data signals corresponding to the image data DATA may be applied to the first to n-th data lines DL1 to DLn. Accordingly, the corresponding sub-pixels SP may generate pieces of light corresponding to the data signals. Accordingly, an image may be displayed on the display panel 110.

In embodiments, the gate driver 120 and the data driver 130 may include complementary metal-oxide semiconductor (CMOS) circuit elements.

The voltage generator 140 may operate in response to a voltage control signal VCS from controller 150. The voltage generator 140 may generate voltages and provide the generated voltages to components of the display device 100. For example, the voltage generator 140 may generate voltages by receiving an input voltage from the outside of the display device 100, adjusting the received voltage, and regulating the adjusted voltage.

The voltage generator 140 may generate a first power supply voltage VDD and a second power supply voltage VSS, and the generated first and second power supply voltages VDD and VSS may be provided to the sub-pixels SP. The first power supply voltage VDD may have a relatively high voltage level, and the second power supply voltage VSS may have a lower voltage level than the first power supply voltage VDD. In other embodiments, the first power supply voltage VDD or the second power supply voltage VSS may be provided by devices outside the display device 100.

For example, the voltage generator 140 may generate various voltages. For example, the voltage generator 140 may generate an initialization voltage to be applied to the sub-pixels SP. For example, during a sensing operation of sensing electrical characteristics of the transistors and/or the light emitting elements of the sub-pixels SP, a certain reference voltage may be applied to the first to n-th data lines DL1 to DLn and the voltage generator 140 may generate the reference voltage.

The controller 150 may control overall operations of the display device 100. The controller 150 may receive, from the outside, input image data IMG and a control signal CTRL for controlling the displaying of the input image data IMG. The controller 150 may provide the gate control signal GCS, the data control signal DCS, and the voltage control signal VCS in response to the control signal CTRL.

The controller 150 may convert the input image data IMG into image data DATA suitable for the display device 100 or the display panel 110 and output the image data DATA. In embodiments, the controller 150 may output the image data DATA by aligning the input image data IMG so as to be suitable for the sub-pixels SP in units of rows.

Two or more components among the data driver 130, the voltage generator 140, and the controller 150 may be mounted on an integrated circuit (e.g., single integrated circuit). As illustrated in FIG. 1, the data driver 130, the voltage generator 140, and the controller 150 may be included in a driver integrated circuit DIC. For example, the data driver 130, the voltage generator 140, and the controller 150 may be functionally separate components within one driver integrated circuit DIC. In other embodiments, at least one of the data driver 130, the voltage generator 140, and the controller 150 may be provided as a component separate from the driver integrated circuit DIC.

The display device 100 may include at least one temperature sensor 160. The temperature sensor 160 may sense ambient temperature and generate temperature data TEP indicating the sensed temperature. In embodiments, the temperature sensor 160 may be disposed adjacent to the display panel 110 and/or the driver integrated circuit DIC.

The controller 150 may control various operations of the display device 100 in response to the temperature data TEP. In embodiments, the controller 150 may adjust the luminance of the image output from the display panel 110 in response to the temperature data TEP. For example, the controller 150 may control the data signals and the first and second power supply voltages VDD and VSS by controlling components such as the data driver 130 and/or the voltage generator 140.

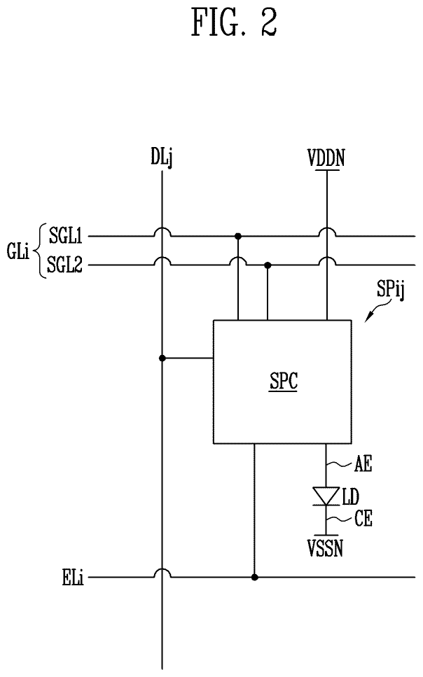

FIG. 2 is a schematic block diagram illustrating a sub-pixel in accordance with an embodiment. FIG. 2 illustrates a sub-pixel SPij arranged in an i-th row (where i is an integer greater than or equal to 1 and less than or equal to m) and a j-th column (where j is an integer greater than or equal to 1 and less than or equal to n) among the sub-pixels SP of FIG. 1.

Referring to FIG. 2, the sub-pixel SPij may include a sub-pixel circuit SPC and a light emitting element LD.

The light emitting element LD may be connected (e.g., electrically connected) between a first power supply voltage node VDDN and a second power supply voltage node VSSN. For example, the first power supply voltage node VDDN may be a node through which the first power supply voltage VDD of FIG. 1 is transmitted, and the second power supply voltage node VSSN is a node through which the second power supply voltage VSS of FIG. 1 is transmitted.

An anode AE of the light emitting element LD may be connected (e.g., electrically connected) to the first power supply voltage node VDDN through the sub-pixel circuit SPC, and a cathode CE of the light emitting element LD may be connected (e.g., electrically connected) to the second power supply voltage node VSSN. For example, the anode AE of the light emitting element LD may be connected (e.g., electrically connected) to the first power supply voltage node VDDN through one or more transistors included in the sub-pixel circuit SPC.

The sub-pixel circuit SPC may be connected (e.g., electrically connected) to an i-th gate line GLi among the first to m-th gate lines GL1 to GLm of FIG. 1, an i-th emission control line ELi among the first to m-th emission control lines EL1 to ELm of FIG. 1, and a j-th data line DLj among the first to n-th data lines DL1 to DLn of FIG. 1. The sub-pixel circuit SPC may control the light emitting element LD according to signals received through these signal lines.

The sub-pixel circuit SPC may operate in response to a gate signal received through the i-th gate line GLi. The i-th gate line GLi may include one or more sub-gate lines. In embodiments, as illustrated in FIG. 2, the i-th gate line GLi may include first and second sub-gate lines SGL1 and SGL2. The sub-pixel circuit SPC may operate in response to the gate signals received through the first and second sub-gate lines SGL1 and SGL2. For example, in case that the i-th gate line GLi includes two or more sub-gate lines, the sub-pixel circuit SPC may operate in response to gate signals received through the corresponding sub-gate lines.

The sub-pixel circuit SPC may operate in response to an emission control signal received through the i-th emission control line ELi. In embodiments, the i-th emission control line ELi may include one or more sub-emission control lines. In case that the i-th emission control line ELi includes two or more sub-emission control lines, the sub pixel circuit SPC may operate in response to emission control signals received through the corresponding sub-emission control lines.

The sub-pixel circuit SPC may receive a data signal through the j-th data line DLj. The sub-pixel circuit SPC may store a voltage corresponding to the data signal in response to at least one of the gate signals received through the first and second sub-gate lines SGL1 and SGL2. The sub-pixel circuit SPC may adjust a current flowing from the first power supply voltage node VDDN through the light emitting element LD to the second power supply voltage node VSSN according to the stored voltage in response to the emission control signal received through the i-th emission control line ELi. Accordingly, the light emitting element LD may generate light with a luminance corresponding to the data signal.

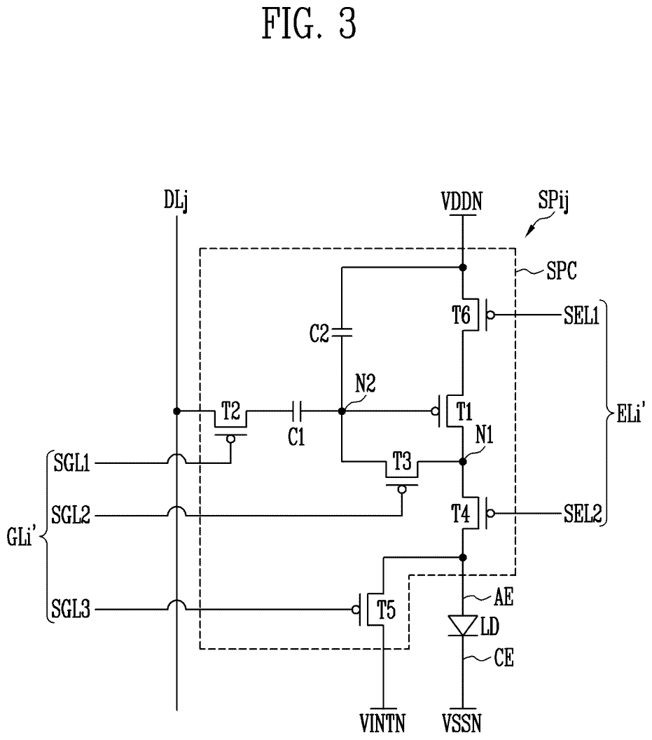

FIG. 3 is a schematic diagram of an equivalent circuit of a sub-pixel in accordance with an embodiment.

Referring to FIG. 3, a sub-pixel SPij may include a sub-pixel circuit SPC and a light emitting element LD.

The sub-pixel circuit SPC may be connected (e.g., electrically connected) to an i-th gate line GLi′, an i-th emission control line ELi′, and a j-th data line DLj. Compared to the i-th gate line GLi of FIG. 2, the i-th gate line GLi′ may further include a third sub-gate line SGL3. Compared to the i-th emission control line ELi of FIG. 2, the i-th emission control line ELi′ may include a first sub-emission control line SEL1 and a second sub-emission control line SEL2.

The sub-pixel circuit SPC may include first to sixth transistors T1 to T6 and first and second capacitors C1 and C2.

The first transistor T1 may be connected (e.g., electrically connected) between the first power supply voltage node VDDN and the first node N1. A gate of the first transistor T1 may be connected (e.g., electrically connected) to a second node N2, and the first transistor T1 may be turned on in response to a voltage level of the second node N2. The first transistor T1 may be referred to as a driving transistor.

The second transistor T2 may be connected (e.g., electrically connected) between the j-th data line DLj and the second node N2. A gate of the second transistor T2 may be connected (e.g., electrically connected) to the first sub-gate line SGL1, and the second transistor T2 may be turned on in response to a gate signal of the first sub-gate line SGL1. The second transistor T2 may be referred to as a switching transistor.

The third transistor T3 may be connected (e.g., electrically connected) between the first node N1 and the second node N2. A gate of the third transistor T3 may be connected (e.g., electrically connected) to the second sub-gate line SGL2, and the third transistor T3 may be turned on in response to a gate signal of the second sub-gate line SGL2.

The fourth transistor T4 may be connected (e.g., electrically connected) between the first node N1 and the anode AE of the light emitting element LD. A gate of the fourth transistor T4 may be connected (e.g., electrically connected) to the second sub-emission control line SEL2, and the fourth transistor T4 may be turned on in response to an emission control signal of the second sub-emission control line SEL2.

The fifth transistor T5 may be connected (e.g., electrically connected) between the anode AE of the light emitting element LD and an initialization voltage node VINTN. The initialization voltage node VINTN may transmit an initialization voltage. In embodiments, the initialization voltage may be provided by the voltage generator 140 of FIG. 1. In other embodiments, the initialization voltage may be provided by a device outside the display device 100. A gate of the fifth transistor T5 may be connected (e.g., electrically connected) to the third sub-gate line SGL3, and the fifth transistor T5 may be turned on in response to a gate signal of the third sub-gate line SGL3.

The sixth transistor T6 may be connected (e.g., electrically connected) between the first power supply node VDDN and the first transistor T1. A gate of the sixth transistor T6 may be connected (e.g., electrically connected) to the first sub-emission control line SEL1, and the sixth transistor T6 may be turned on in response to an emission control signal of the first sub-emission control line SEL1.

The first capacitor C1 may be connected (e.g., electrically connected) between the second transistor T2 and the second node N2. The second capacitor C2 may be connected (e.g., electrically connected) between the first power supply voltage node VDDN and the second node N2.

For example, the sub-pixel circuit SPC may include first to sixth transistors T1 to T6 and first and second capacitors C1 and C2. However, embodiments are not limited thereto. The sub-pixel circuit SPC may be implemented as one of various types of circuits including transistors and one or more capacitors. For example, the sub-pixel circuit SPC may include two transistors and one capacitor. In accordance with embodiments of the sub-pixel circuit SPC, the number of sub-gate lines included in the i-th gate line GLi′ and the number of sub-emission control lines included in the i-th emission control line ELi′ may be changed.

The first to sixth transistors T1 to T6 may each be a P-type transistor. The first to sixth transistors T1 to T6 may each be a metal oxide silicon field effect transistor (MOSFET). However, the embodiments are not limited thereto. For example, at least one of the first to sixth transistors T1 to T6 may be replaced with an N-type transistor.

In embodiments, the first to sixth transistors T1 to T6 may each include an amorphous silicon semiconductor, a polycrystalline silicon semiconductor, a monocrystalline silicon semiconductor, an oxide semiconductor, etc.

The light emitting element LD may include an anode AE, a cathode CE, and an emission layer. The emission layer may be disposed between the anode AE and the cathode CE. After a data signal transmitted through the j-th data line DLj is reflected in a voltage of the second node N2, the fourth and sixth transistors T4 and T6 may be turned on in case that the emission control signals of the first and second sub-emission control lines SEL1 and SEL2 are enabled at low level. For example, the first transistor T1 may be turned on in response to the voltage of the second node N2, and accordingly, a current may flow from the first power supply voltage node VDDN to the second power supply voltage node VSSN. The light emitting element LD may emit light according to the amount of current flowing therethrough.

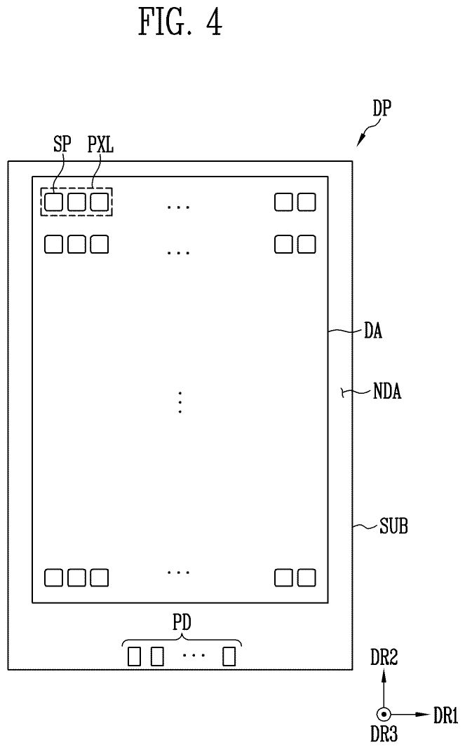

FIG. 4 is a schematic plan view illustrating a display panel in accordance with an embodiment.

Referring to FIG. 4, an embodiment DP of the display panel 110 of FIG. 1 may include a display area DA and a non-display area NDA. The display panel DP may display an image through the display area DA. The non-display area NDA may be disposed around the display area DA.

The display panel DP may include a substrate SUB, sub-pixels SP, and pads PD.

In case that the display panel DP is used as a display screen for a head mounted display (HMD), a virtual reality (VR) device, a mixed reality (MR) device, an augmented reality (AR) device, etc., the display panel DP may be positioned very close to a user's eyes. For example, the sub-pixels SP with relatively high degree of integration may be required. In order to increase the degree of integration of the sub-pixels SP, the substrate SUB may be provided as a silicon substrate. The sub-pixels SP and/or the display panel DP may be formed on the substrate SUB, which is a silicon substrate. The display device (see 100 of FIG. 1) including the display panel DP formed on the substrate SUB, which is a silicon substrate, may be referred to as an OLED on Silicon (OLEDoS) display device.

The sub-pixels SP may be disposed in the display area DA on the substrate SUB. The sub-pixels SP may be disposed in a matrix form in a first direction DR1 and a second direction DR2 intersecting the first direction DR1. However, embodiments are not limited thereto. For example, the sub-pixels SP may be disposed in a zigzag form in the first direction DR1 and the second direction DR2. For example, the sub-pixels SP may be disposed in a PENTILE™ form. The first direction DR1 may be a row direction and the second direction DR2 may be a column direction.

Two or more sub-pixels among the sub-pixels SP may constitute (or formed) a pixel e.g., single pixel) PXL.

Components for controlling the sub-pixels SP may be disposed in the non-display area NDA on the substrate SUB. For example, the lines connected (e.g., electrically connected) to the sub-pixels SP, such as the first to m-th gate lines GL1 to GLm and the first to n-th data lines DL1 to DLn in FIG. 1, may be disposed in the non-display area NDA.

At least one of the gate driver 120, the data driver 130, the voltage generator 140, the controller 150, and the temperature sensor 160 in FIG. 1 may be disposed in the non-display area NDA of the display panel DP. In embodiments, the gate driver 120 of FIG. 1 may be mounted on the display panel DP and disposed in the non-display area NDA. In other embodiments, the gate driver 120 may be implemented as an integrated circuit separate from the display panel DP. In embodiments, the temperature sensor 160 may be disposed in the non-display area NDA to sense the temperature of the display panel DP.

The pads PD may be disposed in the non-display area NDA on the substrate SUB. The pads PD may be electrically connected (e.g., electrically connected) to the sub-pixels SP through the lines. For example, the pads PD may be connected (e.g., electrically connected) to the sub-pixels SP through the first to n-th data lines DL1 to DLn.

The pads PD may interface the display panel DP to other components of the display device (see 100 of FIG. 1). In embodiments, the voltages and the signals necessary for the operations of the components included in the display panel DP may be provided from the driver integrated circuit DIC of FIG. 1 through the pads PD. For example, the first to n-th data lines DL1 to DLn may be connected (e.g., electrically connected) to the driver integrated circuit DIC through the pads PD. For example, the first and second power supply voltages VDD and VSS may be received from the driver integrated circuit DIC through the pads PD. For example, in case that the gate driver 120 is mounted on the display panel DP, the gate control signal GCS may be transmitted from the driver integrated circuit DIC to the gate driver 120 through the pads PD.

In embodiments, a circuit board may be electrically connected (e.g., electrically connected) to the pads PD by using a conductive adhesive member such as an anisotropic conductive film. For example, the circuit board may be a flexible circuit board (FPCB) or a flexible film including a flexible material. The driver integrated circuit DIC may be mounted on the circuit board and electrically connected (e.g., electrically connected) to the pads PD.

In embodiments, the display area DA may have various shapes. The display area DA may have a closed loop shape including straight and/or curved sides. For example, the display area DA may have shapes such as a polygonal shape, a circular shape, a semicircular shape, or an elliptical shape.

In embodiments, the display panel DP may have a flat display surface. In other embodiments, the display panel DP may have a display surface that is at least partially round. In embodiments, the display panel DP may be bendable, foldable, or rollable. In these cases, the display panel DP and/or the substrate SUB may include flexible materials.

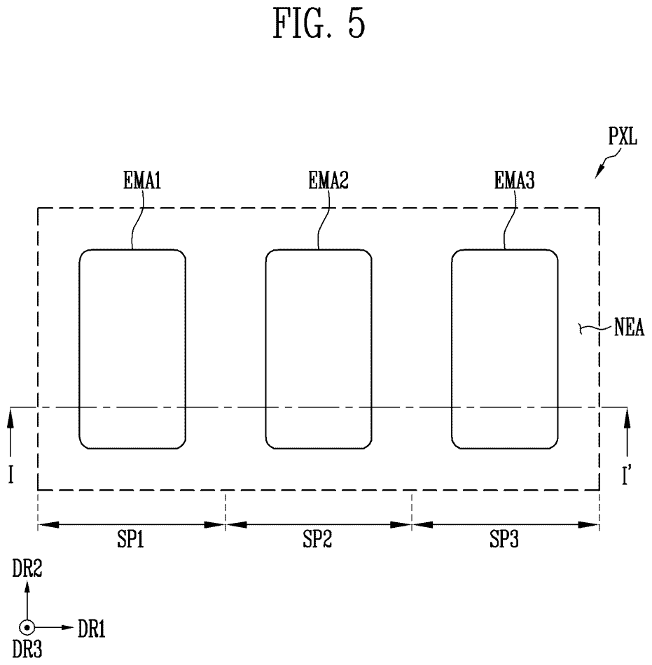

FIG. 5 is a schematic plan view illustrating a pixel in accordance with an embodiment.

Referring to FIG. 5, the pixel PXL may include first to third sub-pixels SP1 to SP3 disposed in the first direction DR1.

The first sub-pixel SP1 may include a first emission area EMA1 and a non-emission area NEA around the first emission area EMA1. The second sub-pixel SP2 may include a second emission area EMA2 and a non-emission area NEA around the second emission area EMA2. The third sub-pixel SP3 may include a third emission area EMA3 and a non-emission area NEA around the third emission area EMA3.

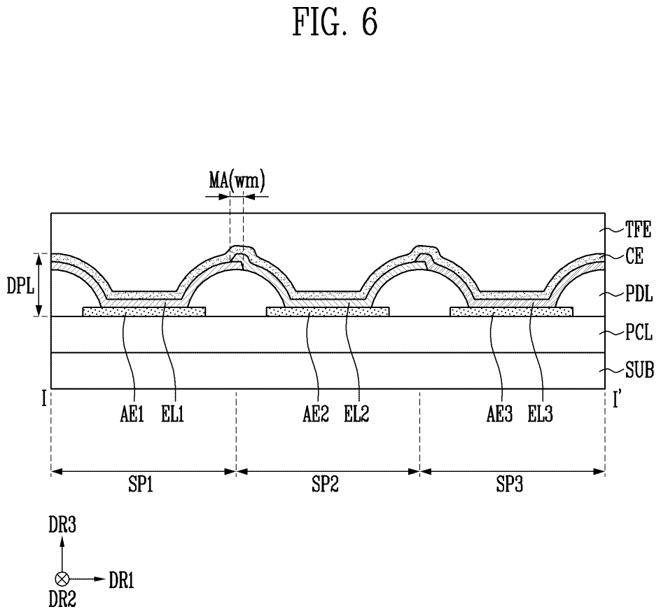

The first emission area EMA1 may be an area in which light is emitted from the first emission layer (see EL1 of FIG. 6) corresponding to the first sub-pixel SP1. The second emission area EMA2 may be an area in which light is emitted from the second emission layer (see EL2 of FIG. 6) corresponding to the second sub-pixel SP2. The third emission area EMA3 may be an area in which light is emitted from the third emission layer (see EL3 of FIG. 6) corresponding to the third sub-pixel SP3.

FIG. 6 is a schematic cross-sectional view taken along line I-I′ of FIG. 5 in accordance with an embodiment.

Referring to FIG. 6, a pixel circuit layer PCL may be disposed on the substrate SUB. The pixel circuit layer PCL may include insulating layers, semiconductor patterns, and conductive patterns, which are stacked on the substrate SUB. The insulating layers may include a buffer layer, one or more interlayer insulating layers, and one or more passivation layers. The semiconductor patterns and the conductive patterns may be disposed between the insulating layers. The conductive patterns may function as at least part of circuit elements, lines, etc. The conductive patterns may include at least one of copper (Cu), molybdenum (Mo), tungsten (W), aluminum neodymium (AlNd), titanium (Ti), aluminum (Al), and silver (Ag), but embodiments are not limited thereto.

The circuit elements may include the sub-pixel circuit (see SPC of FIG. 2) of each of the first to third sub-pixels (see SP1 to SP3 of FIG. 5). The sub-pixel circuit SPC may include transistors and one or more capacitors. The transistors may each include a semiconductor portion and a gate electrode overlapping the semiconductor portion. The semiconductor portion may include a source region, a drain region, and a channel region. In embodiments, in case that the substrate SUB is provided as a silicon substrate, the semiconductor portion may be included in the substrate SUB, and the gate electrode may be included in the pixel circuit layer PCL as the conductive pattern of the pixel circuit layer PCL. In embodiments, in case that the substrate SUB is provided as a glass substrate or a PI substrate, the semiconductor portion and the gate electrode may be provided in the pixel circuit layer PCL. The capacitors may each include electrodes spaced apart from each other. For example, the capacitors may each include electrodes spaced apart from each other in the third direction DR3 with an insulating layer therebetween.

The lines of the pixel circuit layer PCL may include signal lines connected (e.g., electrically connected) to the first to third sub-pixels SP1 to SP3, for example, the gate line, the emission control line, and the data line. The lines may further include a line connected (e.g., electrically connected) to the first power supply voltage node VDDN of FIG. 2. For example, the lines may further include a line connected (e.g., electrically connected) to the second power supply voltage node VSSN of FIG. 2.

In an embodiment, a via layer may be disposed on the pixel circuit layer PCL. The via layer may cover the pixel circuit layer PCL and may have a flat surface as a whole. The via layer may include at least one of silicon oxide (SiOₓ), silicon nitride (SiNₓ), and silicon carbon nitride (SiCN), but embodiments are not limited thereto.

The display element layer DPL may be disposed on the pixel circuit layer PCL. The display element layer DPL may include first to third anodes AE1 to AE3, a pixel defining layer PDL, first to third emission layers EL1 to EL3, and a cathode CE.

The first to third anodes AE1 to AE3 may be disposed on the pixel circuit layer PCL. The first to third anodes AE1 to AE3 may be spaced apart from each other. For example, the first to third anodes AE1 to AE3 may be respectively disposed in the first to third sub-pixels SP1 to SP3. The first anode AE1 may serve (or function) as an anode (see AE of FIG. 2) included in the sub-pixel circuit (see SPC of FIG. 2) of the first sub-pixel SP1. The second anode AE2 may serve (or function) as an anode AE included in the sub-pixel circuit SPC of the second sub-pixel SP2. The third anode AE3 may serve (or function) as an anode AE included in the sub-pixel circuit SPC of the third sub-pixel SP3.

The first to third anodes AE1 to AE3 may each include at least one of transparent conductive materials, such as indium tin oxide (ITO), indium zinc oxide (IZO), zinc oxide (ZnO), indium gallium zinc oxide (IGZO), or indium tin zinc oxide (ITZO). However, embodiments are not limited thereto. For example, the first to third anodes AE1 to AE3 may each include titanium nitride (TiN).

The pixel defining layer PDL may be disposed on the pixel circuit layer PCL. The pixel defining layer PDL may overlap portions of the first to third anodes AE1 to AE3. For example, the pixel defining layer PDL may be disposed (e.g., directly disposed) on portions of the first to third anodes AE1 to AE3. The pixel defining layer PDL may include openings exposing portions of the first to third anodes AE1 to AE3. The openings of the pixel defining layer PDL may respectively define emission areas of the first to third sub-pixels SP1 to SP3. For example, the pixel defining layer PDL may be disposed in the non-emission area (see NEA of FIG. 5) to define the first to third emission areas (see EMA1 to EMA3 of FIG. 5).

The pixel defining layer PDL may include inorganic insulating layers. The inorganic insulating layers may each include at least one of silicon oxide (SiOₓ) and silicon nitride (SiNₓ). For example, the pixel defining layer PDL may include first to third inorganic insulating layers sequentially stacked, and the first to third inorganic insulating layers may each include silicon nitride, silicon oxide, and silicon nitride. However, embodiments are not limited thereto.

The first to third emission layers EL1 to EL3 may be respectively disposed on the first to third anodes AE1 to AE3. For example, the first to third emission layers EL1 to EL3 may be respectively disposed on the first to third anodes AE1 to AE3 exposed by the openings of the pixel defining layer PDL. The first to third emission layers EL1 to EL3 may overlap portions of the pixel defining layer PDL. For example, the first to third emission layers EL1 to EL3 may be disposed (e.g., directly disposed) on portions of the pixel defining layer PDL.

In embodiments, the first emission layer EL1 may emit red color light, the second emission layer EL2 may emit green color light, and the third emission layer EL3 may emit blue color light. The first to third emission layers EL1 to EL3 may each include an organic light emitting material, but embodiments are not limited thereto. For example, the first to third emission layers EL1 to EL3 may each include an inorganic light emitting material, quantum dots, quantum rods, etc.

In embodiments, structures for hole injection, such as a hole injection layer and a hole transport layer, may be further disposed between the first to third anodes AE1 to AE3 and the first to third emission layers EL1 to EL3.

A cathode CE may be disposed on the first to third emission layers EL1 to EL3. The cathode CE may be disposed (e.g., continuously disposed) across the first to third sub-pixels SP1 to SP3. The cathode CE may include a translucent conductive material, such as silver (Ag), a silver alloy, etc., but embodiments are not limited thereto.

In embodiments, structures for electron injection, such as an electron injection layer and an electron transport layer, may be further disposed between the first to third emission layers EL1 to EL3 and the cathode CE.

An encapsulation layer TFE may be disposed on the display element layer DPL. For example, the encapsulation layer TFE may be disposed on the cathode CE. The encapsulation layer TFE may prevent infiltration of external materials, such as oxygen and moisture, into the display element layer DPL. The encapsulation layer TFE may include a structure in which one or more inorganic layers and one or more organic layers are alternately stacked. For example, the inorganic layer may include silicon nitride, silicon oxide, or silicon oxynitride (SiOₓN_{y}). For example, the organic layer may include acrylic resin, epoxy resin, phenolic resin, polyamides resin, polyimides rein, unsaturated polyesters resin, polyphenylenethers resin, polyphenylenesulfides resin, or benzocyclobutene (BCB). However, embodiments are not limited thereto. For example, the encapsulation layer TFE may include aluminum oxide (AlOₓ).

Adjacent emission layers among the first to third emission layers EL1 to EL3 may overlap (e.g., partially overlap) each other. For example, the first emission layer EL1 and the second emission layer EL2 may overlap (e.g., partially overlap) each other on the pixel defining layer PDL. An area where the first emission layer EL1 and the second emission layer EL2 overlap (e.g., partially overlap) each other may be referred to as a color mix area MA. The position and width wm (or size) of the color mix area MA may affect the color reproducibility of the display device (see 100 of FIG. 1). For example, as the color mix area MA is biased (or shifted) toward the first or second emission layer EL1 or EL2 or the width wm of the color mix area MA increases, the deterioration in color reproducibility of the display device 100 may increase. In order to prevent defects in the display device 100 as described above, it may be necessary to measure the position and width wm of the color mix area MA. For example, the width wm of the color mix area MA required to prevent defects in the display device 100 may be about 0.2 μm, but the present disclosure is not necessarily limited thereto.

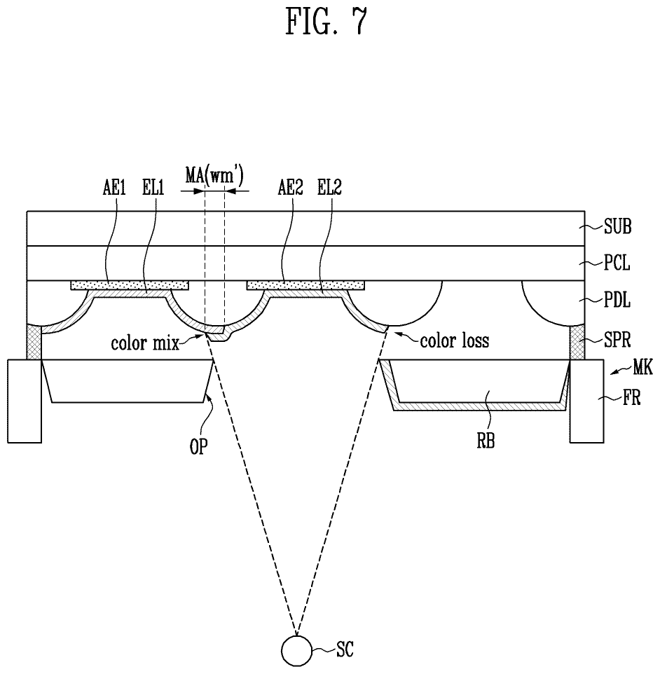

FIG. 7 is a schematic diagram illustrating a deposition process in accordance with an embodiment. FIG. 7 illustrates a process of depositing a second emission layer EL2 after depositing a first emission layer EL1.

Referring to FIG. 7, the second emission layer EL2 may be deposited by using a deposition mask MK and a deposition source SC. The deposition mask MK may include a frame FR and a rib RB attached to the frame FR to define an area. The area may correspond to an opening OP of the deposition mask MK. Organic materials evaporated from the deposition source SC may pass through the opening OP of the deposition mask MK and may be deposited on a second anode AE2 and a pixel defining layer PDL to form the second emission layer EL2.

A spacer SPR may serve (or function) to secure (or ensure) a separation distance. For example, the spacer SPR may be disposed between the pixel defining layer PDL and the deposition mask MK to secure (or ensure) a deposition space. For example, a deposition incidence angle of the organic materials evaporated from the deposition source SC may increase due to the separation distance caused by the spacer SPR. For example, an area of the second emission layer EL2 overlapping the first emission layer EL1 may increase, thereby increasing a width wm′ of the color mix area MA. For example, the width wm′ of the color mix area MA illustrated in FIG. 7 may be greater than the width wm of the color mix area MA illustrated in FIG. 6. For example, as the degree of color mix increases, the deterioration in color reproducibility may increase.

For example, during the deposition process, the organic materials evaporated from the deposition source SC may accumulate on the rib RB of the deposition mask MK, thereby reducing the deposition incidence angle of the organic materials evaporated from the deposition source SC. For example, an area of the second emission layer EL2 deposited on the pixel defining layer PDL may be reduced, thereby resulting in color loss. For example, as the deposition progresses, the degree of color loss may increase, thereby increasing the deterioration of color reproducibility.

Hereinafter, a structure of the display device 100 for measuring the occurrence/non-occurrence and the degree of color mix and color loss occurring in the deposition process and a method of evaluating the display device 100 will be described.

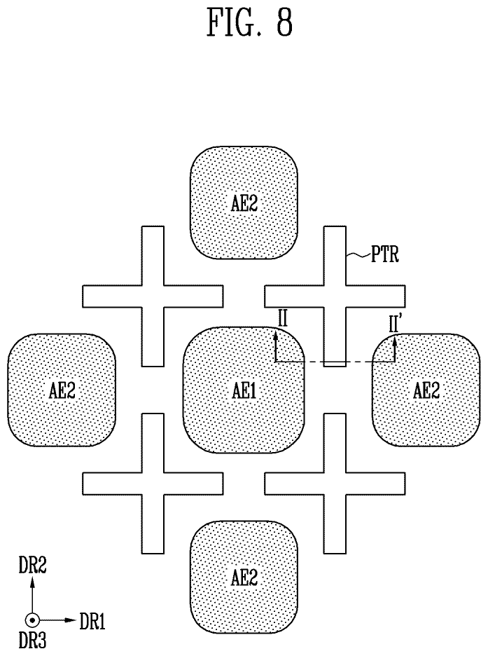

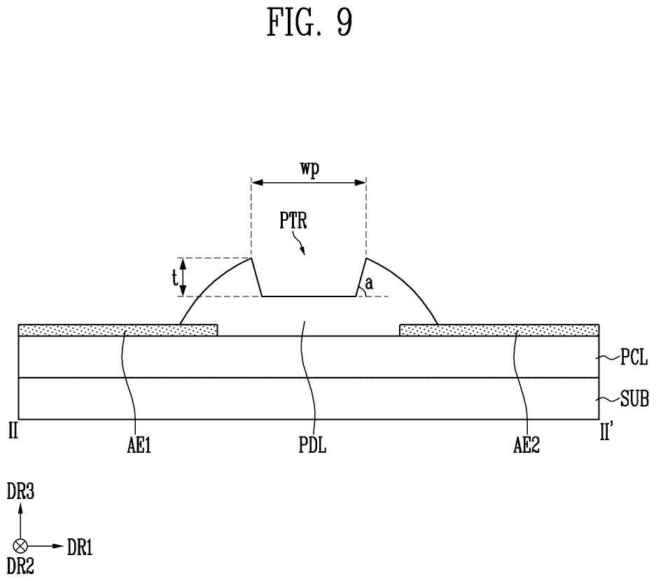

FIG. 8 is a schematic plan view illustrating the arrangement of patterns in accordance with an embodiment. FIG. 9 is a schematic cross-sectional view taken along line II-II′ of FIG. 8 in accordance with an embodiment.

Referring to FIG. 8, patterns PTR positioned between anodes may be provided. For example, the patterns PTR may be recessed patterns, which are formed by etching a portion of the pixel defining layer PDL. The patterns PTR may be disposed so as not to overlap the anodes. The anodes may include a first anode AE1 and second anodes AE2 spaced apart from each other with respect to the first anode AE1. The arrangement structure of the anodes illustrated in FIG. 8 is only an example, and embodiments are not limited thereto.

The patterns PTR may have a cross shape and may be patterned with respect to one anode. For example, the cross-shaped patterns PTR may be spaced apart from each other to correspond (or adjacent) to corner portions of the first anode AE1. For example, the cross-shaped patterns PTR may be spaced apart from each other to correspond (or adjacent) to corner portions of the second anode AE2.

Referring to FIG. 9, the patterns PTR may be formed on a pixel defining layer PDL. For example, the patterns PTR may be formed on a portion of the pixel defining layer PDL that does not overlap the first and second anodes AE1 and AE2.

In embodiments, an edge portion of each of the patterns PTR may be tapered (or inclined). For example, the width of each of the patterns PTR may increase in the third direction DR3 (or the thickness direction). For example, the width of each of the patterns PTR may decrease as being closer to the substrate SUB. For example, a maximum width wp of each of the patterns PTR may be about 0.5 μm or less. For example, a taper angle a of each of the patterns PTR may be about 75° or more and less than about 90°. The taper angle a may refer to an outer angle of each of the patterns PTR. For example, a thickness (or depth) t of each of the patterns PTR may be in a range of about 3,000 angstrom to about 5,000 angstrom. The thickness (or depth) t may be a length measured in the third direction DR3. The patterns PTR may be patterned through a photo process. For example, the patterns PTR may be patterned by applying a photoresist on the first and second anodes AE1 and AE2 and the pixel defining layer PDL and then performing exposure, development, and etching the pixel defining layer PDL. However, embodiments are not limited thereto. For example, the edge portion of each of the patterns PTR may be formed at a right angle without being tapered.

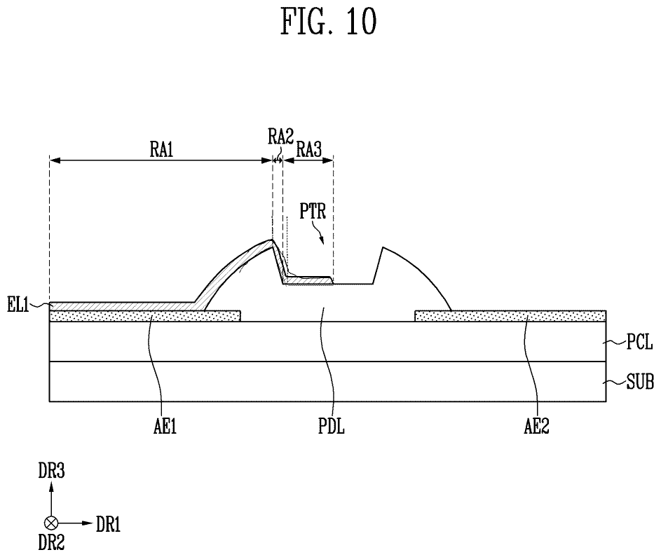

FIGS. 10 to 13 are schematic diagrams describing a method for evaluating a display device in accordance with an embodiment. FIGS. 10 to 13 are schematic diagrams describing a method of evaluating a display device according to color mix (see FIG. 7).

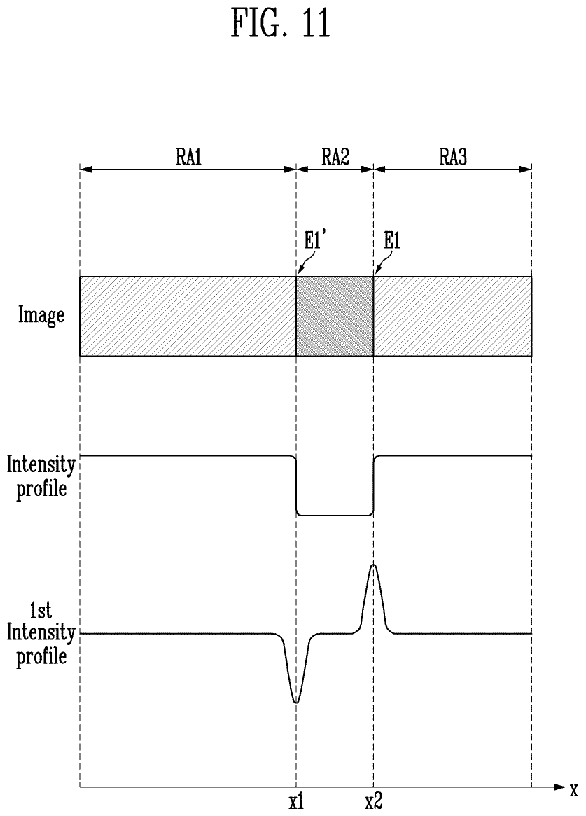

Referring to FIGS. 10 and 11, a first emission layer EL1 may be deposited. The first emission layer EL1 may be deposited by using a deposition mask (see MK of FIG. 7) and a deposition source (see SC of FIG. 7). The first emission layer EL1 may be divided into three areas according to location (or position). For example, a portion of the first emission layer EL1 disposed on a first anode AE1 and a pixel defining layer PDL may be referred to as a first area RA1. For example, a portion of the first emission layer EL1 disposed on a tapered edge portion of a pattern PTR may be referred to as a second area RA2. For example, a portion of the first emission layer EL1 disposed on a lower surface (or a horizontal surface) of the pattern PTR may be referred to as a third area RA3.

Edge detection may be a method of detecting an area (e.g., a boundary line) where brightness changes in an image. The brightness of the first area RA1 appearing in the image may be substantially the same as the brightness of the third area RA3. Since the first area RA1 and the third area RA3 are deposited to be generally flat and little light scattering occurs, the brightness of the image may not change. Referring to an intensity profile illustrated in FIG. 11, it may be confirmed that the brightness of the first area RA1 is substantially the same as the brightness of the third area RA3.

For example, the brightness of the second area RA2 appearing in the image may be different from the brightness of the first area RA1 and the third area RA3. The second area RA2 may be deposited steeply along the tapered edge portion of the pattern PTR, thereby causing a lot of light scattering. Accordingly, the brightness of the image may rapidly decrease. Referring to the intensity profile illustrated in FIG. 11, it may be confirmed that the brightness of the second area RA2 rapidly decreases.

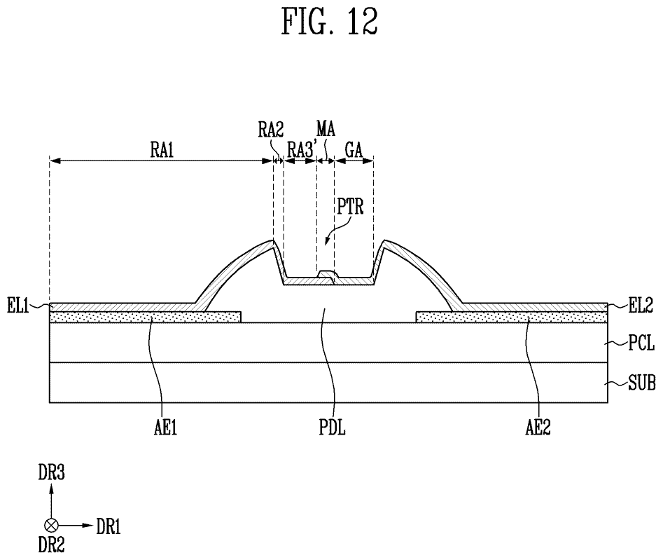

A reference boundary line of the first emission layer EL1 may be detected based on the brightness difference that appears in the image. For example, a boundary line E1′ between the first area RA1 and the second area RA2 may be detected. A position x1 of the boundary line E1′ may be detected through a 1st intensity profile. The position may be an x coordinate in the first direction DR1. In another example, a boundary line E1 between the second area RA2 and the third area RA3 may be detected. A position x2 of the boundary line E1 may be detected through the 1st intensity profile. For example, the reference boundary line of the first emission layer EL1 may be one of the boundary lines E1 and E1′ described above. The reference boundary line of the first emission layer EL1 may serve (or function) as a reference line in case that detecting the position and width (see wm of FIG. 12) of the color mix area (see MA of FIG. 12). Hereinafter, for convenience of explanation, it is assumed that the reference boundary line of the first emission layer EL1 is the boundary line E1 illustrated in FIG. 11, and the reference symbol E1 is assigned to the reference boundary line of the first emission layer EL1.

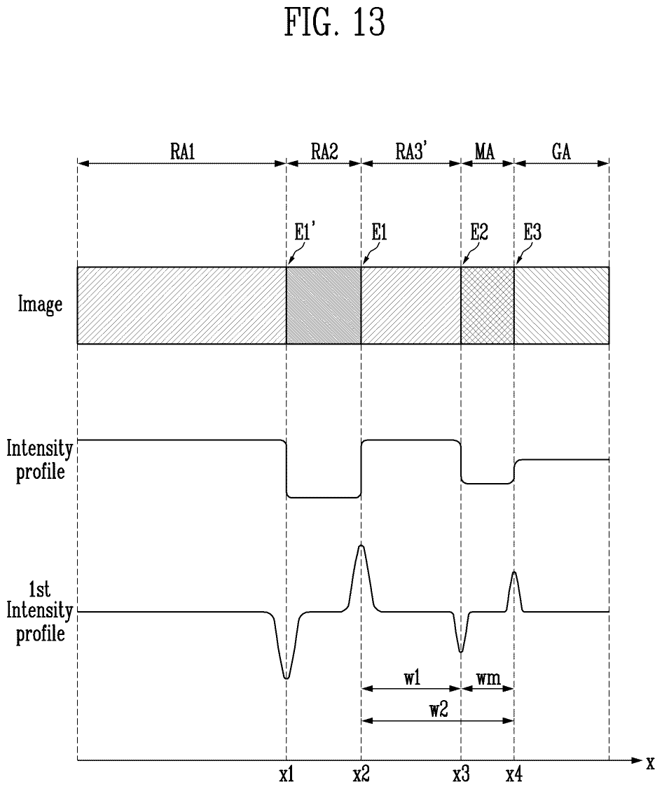

Referring to FIGS. 12 and 13, a second emission layer EL2 may be deposited. For example, a color mix area MA where the first emission layer EL1 overlaps the second emission layer EL2 and an area GA of the second emission layer EL2 disposed on the lower surface of the pattern PTR may be formed. In case that the color mix area MA is formed, a third area RA3′ of the first emission layer EL1 may be reduced.

Referring to an intensity profile illustrated in FIG. 13, the brightness of the color mix area MA appearing in the image may be reduced, compared to the brightness of the third area RA3′. For example, the brightness of the area GA of the second emission layer EL2 appearing in the image may be greater than the brightness of the color mix area MA and less than the brightness of the third area RA3′.

Boundary lines of the second emission layer EL2 may be detected based on the brightness difference that appears in the image. For example, a boundary line E2 between the third area RA3′ and the color mix area MA may be detected. A position x3 of the boundary line E2 may be detected through a 1st intensity profile. For example, a boundary line E3 between the color mix area MA and the area GA of the second emission layer EL2 may be detected. A position x4 of the boundary line E3 may be detected through the 1st intensity profile.

The degree of alignment (or first misalignment) of the first emission layer EL1 and the second emission layer EL2 may be derived (or obtained) based on the reference boundary line E1 of the first emission layer EL1 and the boundary lines E2 and E3 of the second emission layer EL2. The first misalignment may be caused by the overlap of the first emission layer EL1 and the second emission layer EL2 and may be derived (or obtained) based on the width wm and position of the color mix area MA. For example, the width wm of the color mix area MA may be derived (or obtained) based on a gap w1 between the position x2 of the reference boundary line E1 of the first emission layer EL1 and the position x3 of the boundary line E2 of the second emission layer EL2 and a gap w2 between the position x2 of the reference boundary line E1 of the first emission layer EL1 and the position x4 of the boundary line E3 of the second emission layer EL2. In case that the width wm of the color mix area MA is about 0.2 μm, the display device (see 100 of FIG. 1) may be determined to be not defective. In case that the width wm of the color mix area MA exceeds the above-described value, the display device 100 may be determined to be defective.

For example, in case that the value of the gap w1 is greater than a preset (or reference) value, it may be derived (or obtained) that the color mix area MA is biased (or shifted) toward the second emission layer EL2. For example, in case that the value of the gap w1 is less than the preset (or reference) value, it may be derived (or obtained) that the color mix area MA is biased (or shifted) toward the first emission layer EL1. For example, in case that the color mix area MA is biased (or shifted) toward one of the first and second emission layers EL1 and EL2, the display device 100 may be determined to be defective. In case that the position of the color mix area MA matches a preset (or reference) position, the display device 100 may be determined to be not defective. For example, it is possible to determine whether the display device 100 is defective by deriving (or obtaining) the position of the color mix area MA based on the reference boundary line E1 of the first emission layer EL1.

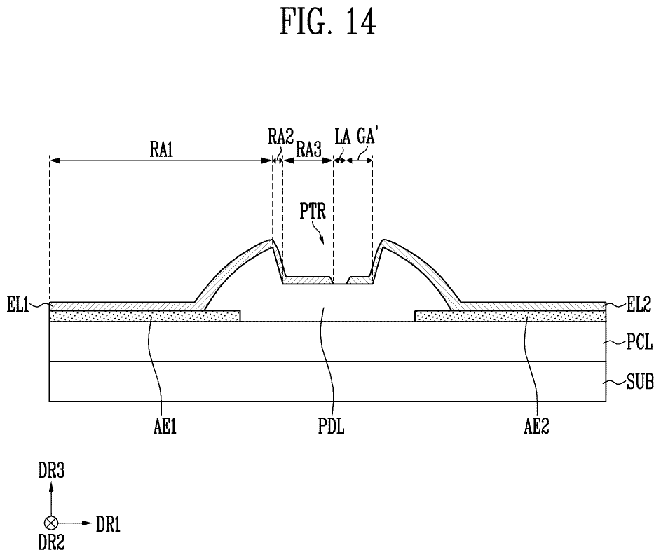

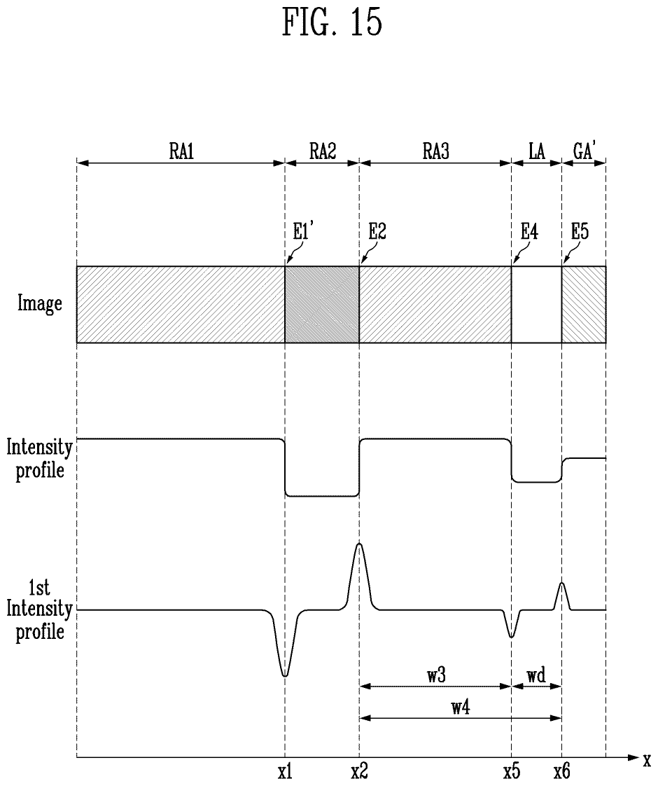

FIGS. 14 and 15 are schematic diagrams describing a method for evaluating a display device in accordance with an embodiment. FIGS. 14 and 15 are schematic diagrams describing a method of evaluating a display device according to color loss (see FIG. 7).

Referring to FIGS. 14 and 15, a second emission layer EL2 may be deposited. For example, the second emission layer EL2 may not be completely deposited on the lower surface of the pattern PTR, and a color loss area LA may be formed. The color loss area LA may refer to an area of the pattern PTR in which the second emission layer EL2 is not deposited. In case that the color loss area LA is formed, an area GA′ of the second emission layer EL2 may be reduced.

Referring to an intensity profile illustrated in FIG. 15, the brightness of the color loss area LA appearing in the image may be reduced, compared to the brightness of the third area RA3. For example, the brightness of the area GA′ of the second emission layer EL2 appearing in the image may be greater than the brightness of the color loss area LA and less than the brightness of the third area RA3.

A boundary line E4 of the first emission layer EL1 may be detected based on the brightness difference that appears in the image. For example, the boundary line E4 between the third area RA3 and the color loss area LA may be detected. A position x5 of the boundary line E4 may be detected through a 1st intensity profile.

A boundary line E5 of the second emission layer EL2 may be detected based on the brightness difference that appears in the image. For example, the boundary line E5 between the color loss area LA and the area GA′ of the second emission layer EL2 may be detected. A position x6 of the boundary line E5 may be detected through the 1st intensity profile.

The degree of alignment (or second misalignment) of the first emission layer EL1 and the second emission layer EL2 may be derived (or obtained) based on the reference boundary line E1 and the boundary line E4 of the first emission layer EL1 and the boundary line E5 of the second emission layer EL2. The second misalignment is caused by the loss of the second emission layer EL2 and may be derived (or obtained) based on the width wd and position of the color loss area LA. For example, the width wd of the color loss area LA may be derived (or obtained) based on a gap w3 between the position x2 of the reference boundary line E1 of the first emission layer EL1 and the position x5 of the boundary line E4 of the first emission layer EL1 and a gap w4 between the position x2 of the reference boundary line E1 of the first emission layer EL1 and the position x6 of the boundary line E5 of the second emission layer EL2. In case that the width wd of the color loss area LA satisfies a preset (or reference) value, the display device (see 100 of FIG. 1) may be determined to be not defective. For example, in case that the width wd of the color loss area LA exceeds the preset (or reference) value, the display device 100 may be determined to be defective.

For example, in case that the value of the gap w4 is greater than a preset (or reference) value, it may be derived (or obtained) that the color loss area LA is biased (or shifted) toward the second emission layer EL2. For example, in case that the value of the gap w4 is less than the preset (or reference) value, it may be derived (or obtained) that the color loss area LA is biased (or shifted) toward the first emission layer EL1. For example, in case that the color loss area LA is biased (or shifted) toward one of the first and second emission layers EL1 and EL2, the display device 100 may be determined to be defective. In case that the position of the color loss area LA matches a preset (or reference) position, the display device 100 may be determined to be not defective. It is possible to determine whether the display device 100 is defective by deriving (or obtaining) the position of the color loss area LA based on the reference boundary line E1 of the first emission layer EL1.

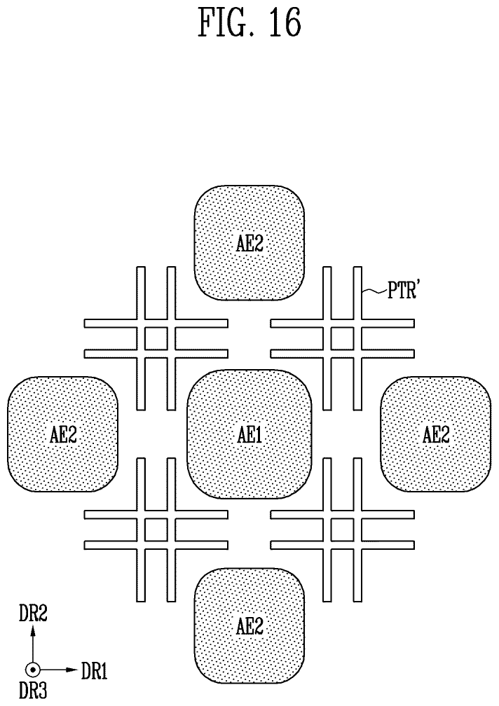

FIG. 16 is a schematic plan view illustrating the arrangement of patterns in accordance with an embodiment. With regard to FIG. 16, descriptions redundant with those provided above with reference to FIG. 8 are simplified or omitted.

Referring to FIG. 16, patterns PTR′ positioned between anodes may be provided. The patterns PTR′ may be disposed so as not to overlap the anodes. The patterns PTR′ may have a matrix shape and may be patterned with respect to one anode. For example, the matrix-shaped patterns PTR′ may be spaced apart from each other to correspond (or adjacent) to corner portions of the first anode AE1. For example, the matrix-shaped patterns PTR′ may be spaced apart from each other to correspond (or adjacent) to corner portions of the second anode AE2.

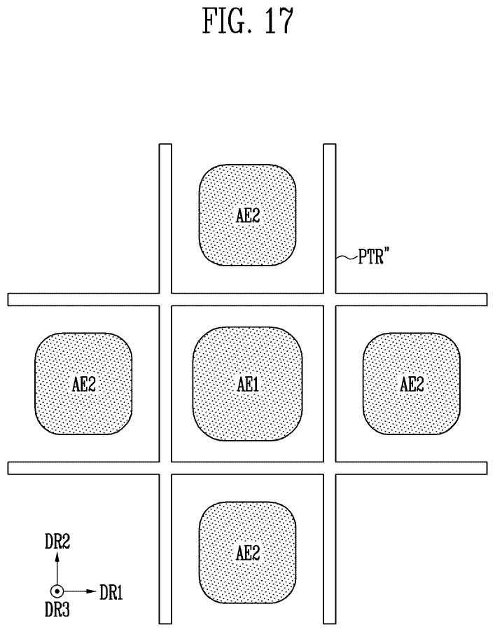

FIG. 17 is a schematic plan view illustrating the arrangement of patterns in accordance with an embodiment. With regard to FIG. 17, descriptions redundant with those provided above with reference to FIG. 8 are simplified or omitted.

Referring to FIG. 17, patterns PTR″ positioned between anodes may be provided. The patterns PTR″ may be disposed so as not to overlap the anodes. The pattern PTR″ has a matrix shape and may be patterned (e.g., continuously patterned). For example, the pattern PTR″ having a matrix shape may be disposed to surround a first anode AE1. For example, the pattern PTR″ having a matrix shape may be disposed to surround a second anode AE1.

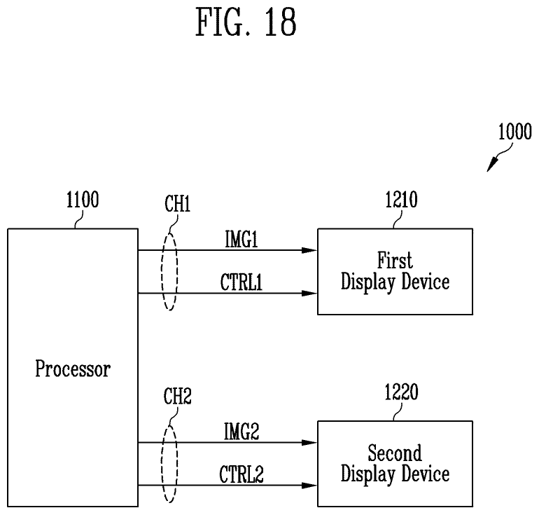

FIG. 18 is a schematic block diagram illustrating a display system in accordance with an embodiment.

Referring to FIG. 18, a display system 1000 may include a processor 1100 and one or more display devices 1210 and 1220.

The processor 1100 may perform various tasks and calculations. In embodiments, the processor 1100 may include an application processor, a graphics processor, a microprocessor, a central processing unit (CPU), etc. The processor 1100 may be connected (e.g., electrically connected) to other components of the display system 1000 through a bus system and may control the components of the display system 1000.

FIG. 18 illustrates that the display system 1000 includes first and second display devices 1210 and 1220. The processor 1100 may be connected (e.g., electrically connected) to the first display device 1210 through a first channel CH1 and connected (e.g., electrically connected) to the second display device 1220 through a second channel CH2.

The processor 1100 may transmit first image data IMG1 and a first control signal CTRL1 to the first display device 1210 through the first channel CH1. The first display device 1210 may display an image based on the first image data IMG1 and the first control signal CTRL1. The first display device 1210 may be configured (or formed) similarly to the display device 100 described above with reference to FIG. 1. For example, the first image data IMG1 and the first control signal CTRL1 may be provided as the input image data IMG and the control signal CTRL of FIG. 1, respectively.

The processor 1100 may transmit second image data IMG2 and a second control signal CTRL2 to the second display device 1220 through the second channel CH2. The second display device 1220 may display an image based on the second image data IMG2 and the second control signal CTRL2. The second display device 1220 may be configured (or formed) similarly to the display device 100 described above with reference to FIG. 1. For example, the second image data IMG2 and the second control signal CTRL2 may be provided as the input image data IMG and the control signal CTRL of FIG. 1, respectively.

The display system 1000 may include a computing system that provides an image display function, such as a portable computer, a mobile phone, a smart phone, a tablet personal computer, a smart watch, a watch phone, a portable multimedia player (PMP), a navigation system, or an ultra mobile personal computer (UMPC). For example, the display system 1000 may include at least one selected from an HMD, a VR device, an MR device, or an AR device.

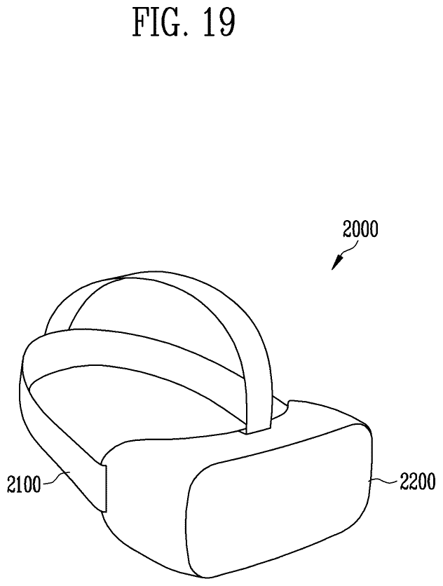

FIG. 19 is a schematic perspective view illustrating an application example of the display system of FIG. 18.

Referring to FIG. 19, the display system 1000 of FIG. 18 may be applied to an HMD 2000. The HMD 2000 may be a wearable electronic device that is wearable on a user's head.

The HMD 2000 may include a head mounted band 2100 and a display device storage case 2200. The head mounted band 2100 may be connected (e.g., electrically connected) to the display device storage case 2200. The head mounted band 2100 may include a horizontal band and/or a vertical band for fixing the HMD 2000 to the user's head. The horizontal band may surround the sides of the user's head, and the vertical band may surround the upper portion of the user's head. However, embodiments are not limited thereto. For example, the head mounted band 2100 may be implemented in the form of glasses frames, helmets, etc.

The display device storage case 2200 may accommodate the first and second display devices 1210 and 1220 of FIG. 18. The display device storage case 2200 may further accommodate the processor 1100 of FIG. 18.

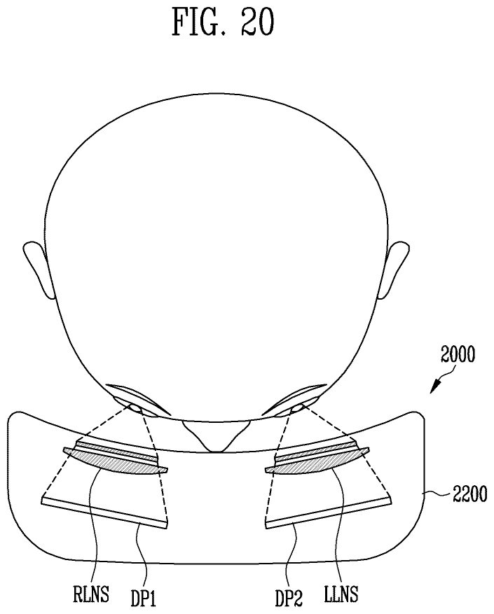

FIG. 20 is a schematic diagram illustrating the HMD of FIG. 19 that is worn by a user.

Referring to FIG. 20, a first display panel DP1 of the first display device 1210 and a second display panel DP2 of the second display device 1220 are disposed in the HMD 2000. The HMD 2000 may further include one or more lenses LLNS and RLNS.

The right eye lens RLNS may be disposed between the first display panel DP1 and the user's right eye within the display device storage case 2200. The left eye lens LLNS may be disposed between the second display panel DP2 and the user's left eye within the display device storage case 2200.

An image output from the first display panel DP1 may be displayed to the user's right eye through the right eye lens RLNS. The right eye lens RLNS may refract light from the first display panel DP1 so as to be directed toward the user's right eye. The right eye lens RLNS may perform an optical function for adjusting the viewing distance between the first display panel DP1 and the user's right eye.

An image output from the second display panel DP2 may be displayed to the user's left eye through the left eye lens LLNS. The left eye lens LLNS may refract light from the second display panel DP2 so as to be directed toward the user's left eye. The left eye lens LLNS may perform an optical function for adjusting the viewing distance between the second display panel DP2 and the user's left eye.

In embodiments, the right eye lens RLNS and the left eye lens LLNS may each include an optical lens having a pancake-shaped cross section. In embodiments, the right eye lens RLNS and the left eye lens LLNS may each include a multi-channel lens including sub-regions with different optical properties. For example, each display panel may output images corresponding to the sub-regions of the multi-channel lens, and the output images may pass through the corresponding sub-regions and may be displayed to the user.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a substrate;
a pixel circuit layer disposed on the substrate;
anodes spaced apart from each other and disposed on the pixel circuit layer;
a pixel defining layer disposed on portions of the anodes and the pixel circuit layer; and
patterns formed on the pixel defining layer,
wherein an edge portion of each of the patterns is tapered.

2. The display device according to claim 1, wherein the patterns are disposed between the anodes and do not overlap the anodes.

3. The display device according to claim 1, wherein the patterns are formed to be adjacent to corner portions of each of the anodes.

4. The display device according to claim 1, wherein
each of the patterns has a cross shape in plan view, and
the patterns are spaced apart from each other.

5. The display device according to claim 1, wherein a width of each of the patterns decreases as being closer to the substrate.

6. The display device according to claim 5, wherein a maximum value of the width of each of the patterns is about 0.5 μm or less.

7. The display device according to claim 1, wherein a depth of each of the patterns is in a range of about 3,000 angstrom to about 5,000 angstrom.

8. The display device according to claim 1, wherein a taper angle of the edge portion is about 75° or more and less than about 90°.

9. The display device according to claim 1, wherein
each of the patterns has a matrix shape in plan view, and
the patterns are spaced apart from each other.

10. A display device comprising:
a substrate;
a pixel circuit layer disposed on the substrate;
anodes spaced apart from each other and disposed on the pixel circuit layer;
a pixel defining layer disposed on portions of the anodes and the pixel circuit layer; and
a pattern formed on the pixel defining layer and having a matrix shape in plan view,
wherein an edge portion of the pattern is tapered.

11. A method of evaluating a display device comprising a pattern on a pixel defining layer and having a tapered edge portion, the method comprising:
detecting a reference boundary line of a first emission layer;
detecting boundary lines of a second emission layer;
obtaining a degree of alignment of the first emission layer and the second emission layer based on the reference boundary line and the boundary lines; and
determining whether the display device is defective, based on the degree of alignment.

12. The method according to claim 11, wherein the reference boundary line is a boundary line between an area of the first emission layer that overlaps the tapered edge portion of the pattern and an area of the first emission layer that overlaps a lower surface of the pattern.

13. The method according to claim 12, wherein the boundary lines of the second emission layer comprise:
a first boundary line between an area of the second emission layer that overlaps the first emission layer and an area of the first emission layer that overlaps the lower surface of the pattern; and
a second boundary line between an area of the second emission layer that overlaps the first emission layer and an area of the second emission layer that overlaps the lower surface of the pattern.

14. The method according to claim 13, wherein the obtaining of the degree of alignment of the first emission layer and the second emission layer comprises:
obtaining a first gap between the reference boundary line and the first boundary line;
obtaining a second gap between the reference boundary line and the second boundary line; and
obtaining a width of a color mix area where the first emission layer overlaps the second emission layer, based on the first gap and the second gap.

15. The method according to claim 14, wherein the determining of whether the display device is defective comprises checking whether the width of the color mix area corresponds to a reference value.

16. A method of evaluating a display device comprising a pattern on a pixel defining layer and having a tapered edge portion, the method comprising:
detecting boundary lines of a first emission layer;
detecting a boundary line of a second emission layer;
obtaining a degree of alignment of the first emission layer and the second emission layer, based on the boundary lines of the first emission layer and the boundary line of the second emission layer; and
determining whether the display device is defective, based on the degree of alignment.

17. The method according to claim 16, wherein the boundary lines of the first emission layer comprise:
a reference boundary line between an area of the first emission layer that overlaps the tapered edge portion of the pattern and an area of the first emission layer that overlaps a lower surface of the pattern; and
a boundary line between the area of the first emission layer that overlaps the lower surface of the pattern and an area of the pattern.

18. The method according to claim 17, wherein the boundary line of the second emission layer is a boundary line between an area of the second emission layer that overlaps the lower surface of the pattern and the area of the pattern.

19. The method according to claim 18, wherein the obtaining of the degree of alignment of the first emission layer and the second emission layer comprises:
obtaining a first gap between the reference boundary line and the boundary line of the first emission layer;
obtaining a second gap between the reference boundary line and the boundary line of the second emission layer; and
obtaining a width of a color loss area where the first emission layer does not overlap the second emission layer, based on the first gap and the second gap.

20. The method according to claim 19, wherein the determining of whether the display device is defective comprises checking whether the width of the color loss area corresponds to a reference value.
